(19) United States
(12) Patent Application Publication
(10) Pub. No.: US 2006/0219549 A1
(43) Pub. Date: Oct. 5, 2006

(54) Sputtering target of silver alloy for producing reflection layer of optical recording medium

(75) Inventors: Akifumi Mishima, Sanda-shi Hyogo-ken (JP); Satoshi Fujita, Sanda-shi (JP); Masahiro Syoji, Sanda-shi (JP)

Correspondence Address: DARBY & DARBY P.C., P. O. BOX 5257, NEW YORK, NY, 10150-5257, US

(73) Assignee: Mitsubishi Materials Corporation, Tokyo (JP)

(21) Appl. No.: 10/557,373

(22) PCT Filed: May 16, 2003
(86) PCT No.: PCT/JP03/06135

§ 371 Date: Nov. 14, 2005

(51) Int. Cl. C23C 14/00

(52) U.S. Cl. 204/298.13; 428/823.2

(57) ABSTRACT

Ag alloy sputtering target of the invention comprises (1) an Ag alloy containing 0.1 to 20 wt % of Zn, 0.1 to 3 wt % of Al, and a balance of Ag, (2) an Ag alloy containing 0.1 to 20 wt % of Zn, 0.1 to 3 wt % of Al, totally 0.005 to 0.05 wt % of one or more elements selected from Ca, Be, and Si, and a balance of Ag, or (3) an Ag alloy containing 0.5 to 5 wt % of Cu, 0.05 to 2 wt % of Ni, and a balance of Ag

### TECHNICAL FIELD

The present invention relates to a sputtering target of silver alloy for producing full reflection layer and semi-reflection layer (both of which are hereafter called a reflection layer) in an optical recording medium such as an optical recording disk (CD-RW, DVD-RAM) or the like for recording/replaying/erasing information signals of sounds; images, characters or the like utilizing a laser beam of a semiconductor laser or the like.

### BACKGROUND ART

An optical recording medium such as an optical recording disk has two recording layers, a first recording layer on which a laser beam is incident, and a second recording layer distant from the laser beam source compared to the first recording layer. By forming the recording layer with a phase-change recording material, recording, replaying, and erasing processes can be repeated. To increase recording density of the optical recording mediums, utilization of a blue-violet laser generating laser beam of short wavelength has been extensively studied. In the optical recording medium, it is necessary to provide a semi-reflection layer on the side of laser incidence on the recording layer so that the laser effectively transmits the semi-reflection layer, and records, replays, and erases information signals on the second recording layer. On the other hand, to record, replay, and erase recording signals on the first recording layer, the semi-reflection layer must be provided with sufficient cooling efficiency, and reflectivity.

Ag or Ag alloy layers are conventionally used as reflection layers such as full reflection layers and semi-reflection layers having the above described functions on an optical recording medium such as an optical recording disk (CD-RW, DVD-RAM) or the like. The Ag or Ag alloy layers are prefer because they have high reflectance over a wide range of wavelengths from 400 to 830 nm. Especially, they have high reflectance for a short wavelength laser beam used to increase recording densities of optical recording mediums. It is known that the Ag or Ag alloy layers may be formed by sputtering a target comprising a Ag or Ag alloy such as Ag—Zn alloy, Ag—Cu alloy (Japanese Unexamined Patent Application, First Publication No. S57-186244; Japanese Unexamined Patent Application, First Publication No.2001-35014).

However, when the conventional Ag layer or Ag alloy layer is used as a full reflection layer, sufficient replaying ability over a long period cannot be obtained because of deterioration of reflectance along with repeat of recording, replaying, and erasing of data A cause of such deterioration is considered as following. When recording, replaying, and erasing data are repeated in an optical recording medium, repeated heating and cooling of the full reflection layer due to the laser incidence cause recrystallization and coarsening of the crystal grains of the Ag or Ag alloy layers, thereby lowering the reflectance.

Moreover, when the conventional Ag or Ag alloy layer was used as semi-reflection layer, consumption of laser beam energy by the semi-reflection layer could not be avoided because of insufficient transmittance and reflection of the laser beam. In addition, because of alteration of reflection and transmission ratio accompanying an increasing number of repetitions of recording/replaying/erasing the data, sufficient durability for data replaying could not be obtained. A cause of such alteration is considered as follows. When recording, replaying, and erasing data are repeated in an optical recording medium, repeated heating and cooling of the semi-reflection layer due to the laser beam incidence cause diffusion which is accompanied by aggregation and recrystallization of crystal grains of the semi-reflection S layer. In addition, when atoms migrate from a portion of the thin film of the semi-reflection layer by atomic diffusion, since there is no supply source of atoms, holes are generated in the film.

### DISCLOSURE OF THE INVENTION

A first aspect of the invention is a sputtering target of a Ag alloy for producing reflection layers of optical recording mediums, and the Ag alloy comprising the target is selected from the following (1) to 14);
(1) Ag alloy containing 0.1 to 20 wt % (% by weight) of Zn, 0.1 to 3 wt % of Al, and a balance of Ag;
(2) Ag alloy containing 0.1 to 20 wt % of Zn, 0.1 to 3 wt % of Al , totally 0.005 to 0.05 wt % of one or more elements selected from Ca, Be, and Si, and a balance of Ag;
(3) Ag alloy containing 0.1 to 20 wt % of Zn, 0.1 to 3 wt % of Al, totally 0.1 to 3wt % of one or more elements selected from Dy, La, Nd, Tb, and Gd, and a balance of Ag;
(4) Ag alloy containing 0.1 to 20 wt % of Zn, 0.1 to 3 wt % of Al, totally 0.005 to 0.05 wt % of one or more elements selected from Ca, Be, and Si, totally 0.1 to 3 wt % of one or more elements selected from Dy, La, Nd, Th, and Gd, and a balance of Ag.

An Ag alloy sputtering target described in the first aspect can be used to form full reflection layers of optical recording mediums. For specifically producing full reflection layers of the optical recording mediums, it is preferable to use an Ag alloy sputtering target in which the Zn content is not less than 1 wt % and the Al content is not less than 0.5 wt %.

Accordingly, a second aspect of the invention is an Ag alloy sputtering target for producing full reflection layers of optical recording mediums and is formed of Ag alloy selected from the following (6) to (9):
(6) Ag alloy containing 1 to 20 wt % of Zu, 0.5 to 3 wt % of Al, and a balance of Ag;
(7) Ag alloy containing 1 to 20 wt % of Zn, 0.5 to 3 wt % of Al, totally 0.005 to 0.05 wt % of one or more elements selected from Ca, Be, and Si, and a balance of Ag;
(8) Ag alloy containing 1 to 20 wt % of Zn, 0.5 to 3 wt To of Al, totally 0.1 to 3 wt % of one or more elements selected from Dy, La, Nd, Th, and Gd, and a balance of Ag;
(9) Ag alloy containing 1 to 20 wt % of Zn, 0,5 to 3 wt % of Al, totally 0.005 to 0.05 wt % of one or more elements selected fmom Ca, Be, and Si, totally 0.1 to 3wt % of one or more elements selected from Dy, La, Nd, Ib, and Gd, and a balance of Ag.

On the other hand, in order to form a semi-reflection layer of an optical recording medium, it is preferable to use a sputtering target of Ag alloy prepared to contain less than 1 wt % of Zn, less than 0.5 wt % of Al, and where necessary, additionally contain totally 0.005 to 0.05 wt % of one or more elements selected from Ca, Be, and Si.

Accordingly, a third aspect of the present invention is an Ag alloy sputtering target for producing semi-reflection layers of optical recording mediums and is formed of Ag alloy of following (11) or (12):
(11) Ag alloy containing 0.1 to less than 1 wt % of Zn, 0.1 to less than 0.5 wt % of Al, and a balance of Ag;
(12) Ag alloy containing 0.1 to less than 1 wt % of Zn, 0.1 to less than 0.5 wt % of Al, totally 0.005 to 0.05 wt % of one or more elements selected from Ca, Be, and Si, and a balance of Ag.

To produce suttering targets of the invention, highly pure Ag, Zn, and Al each having a purity of not less than 99.9 wt % and Dy, La, Nd, Th, and Gd each having a purity of not less than 99.9 wt % are prepared as raw materials. The raw materials are melted under high vacuum conditions or in an inert gas atmosphere. Ingots are formed by casting the molten metal under high vacuum conditions or in an inert gas atmosphere. By hot working and subsequently mechanically working the ingots, sputtering targets are produced.

Ca, Be, and Si are hardly soluble in Ag in a solid state. Therefore, Ca, Be, and Si are preliminarily compounded with Ag so as to have a content of 0.20 wt % respectively. Subsequently, the compound is melted by radio frequency vacuum melting. After the melting, Ar gas is introduced into the furnace so that the Ar atmosphere in the furnace has an ambient pressure, and molten metal is cast into graphite molds and a master alloy confining Ca, Be, and Si is prepared. Ingots are prepared by adding this alloy with Zn, and Al to Ag, and melting them and casting the melt. By hot working and subsequently mechanically working the ingots, the sputtering targets are produced.

A fourth aspect of the present invention is an Ag alloy sputtering target for producing reflection layers of optical recording mediums and is formed of Ag alloy selected from the following (13) to (16):
(13) Ag alloy containing 0.5 to 5 wt % of Cu, 0.05 to 2 wt % of Ni, and a balance of Ag;
(14) Ag alloy containing 0.5 to 5 wt % of Cu, 0.05 to 2 wt % of Ni, additionally containing totally 0.005 to 0.05 wt % of one or more elements selected from Ca, Be, and Si, and a balance of Ag;
(15) Ag alloy containing 0.5 to 5 wt % of Cu, 0.05 to 2 wt % Ni, additionally containing totally 0.1 to 3 wt % of one or more elements selected from Dy, La, Nd, Th, and Gd, and a balance of Ag;
(16) Ag alloy containing 0.5 to 5 wt % of Cu 0.05 to 2 wt % of Ni, totally 0.005 to 0.05 wt % of one or more elements selected from Ca, Be, and Si, totally 0.1 to 3 wt % of one or more elements selected from Dy, La, Nd, Th, and Gd, and a balance of Ag.

The sputtering targets of the invention can be produced by the following process. As raw materials, highly pure Ag, Cu each having a purity of not less than 99.9 wt %, and Ni, Dy, La, Nd, Tb, and Gd each having a purity of not less than 99.9 wt % are prepared. The raw materials are melted under high vacuum conditions or in an inert gas atmosphere. Ingots are formed by casting the molten metal under high vacuum conditions or in an inert gas atmosphere. By hot working and subsequently mechanically working the ingots, sputtering targets are produced.

Ca, Be, and Si are hardly soluble in Ag in a solid state. Therefore, Ca, Be, and Si are preliminarily compounded with Ag so as to have a content of 0.20 wt % respectively. Subsequently, the compound is melted by radio frequency vacuum melting. After the melting, Ar gas is introduced into the furnace so that the Ar gas has an ambient pressure, and molten metal is cast into graphite molds and master alloy containing Ca, Be, and Si is prepared. In a similar manner, with regard to Ni hardly forming a solid solution with Ag, Ni is firstly alloyed with Cu so as to have a content of 5 to 95 wt %. Subsequently, the alloy is melted by radio frequency vacuum melting. After the melting, Ar gas is introduced into the furnace so that the Ar gas has an to ambient pressure, and molten metal is cast into a graphite mold and a master Cu alloy containing Ni is prepared. Copper is optionally added to these master alloys, which are melted and cast to form ingots. By hot working and mechanically working the ingots, sputtering targets are produced.

### BEST MODE FOR CARRYING OUT THE INVENTION

The inventors studied to realize Ag alloy layers for providing full reflection layers having low deterioration of reflectance under an increasing number of repeatings of recording/replaying/erasing, and semi-reflection layers showing low deterioration of transmittance and reflectance under an increasing number of repeatings of recording/replaying/erasing. The results are as follows:

(A) Compared with Ag or Ag alloy layers produced by sputtering using conventional Ag or Ag—Zn alloy sputtering targets, Ag alloy layers produced by sputtering using an Ag alloy target of Ag—Zn alloy containing 0.1 to 20 wt % of Zn, 0.1 to 3 wt % of Al show little coarsening of crystal grains by repeated heating and cooling due to repeated incidence of a laser beam, and the layers show very little deterioration of reflectance after long-term use.

(B) Compared with Ag or Ag alloy layers produced by sputtering using conventional Ag or Ag—Zn alloy sputtering targets, in Ag alloy layers produced by sputtering using an Ag alloy target of Ag—Zn alloy containing 0.1 to 20 wt % of Zn, 0.1 to 3 wt % of Al, additionally containing totally 0.005 to 0.05 wt % of one or more elements selected from Ca, Be, and Si, coarsening of crystal grains by repeated heating and cooling due to repeated incidence of a laser beam is further reduced, and therefore, the layers show very little deterioration of reflectance after long-term use.

(C) Compared with Ag or Ag alloy layers produced by sputtering using conventional Ag or Ag—Zn alloy sputtering targets, in Ag alloy layers produced by sputtering using an Ag alloy target of Ag—Zn alloy containing 0.1 to 20 wt % of Zn, 0.1 to 3 wt % of Al, additionally containing totally 0.1 to 3 wt % of one or more elements selected from Dy, La, Nd, Th, and Gd, coarsening of crystal grains by repeated heating and cooling due to repeated incidence of a laser beam is further reduced, and therefore, the layers show very little deterioration of reflectance after long-term use.

(D) Ag alloy layers produced by sputtering using an Ag alloy target of Ag—Zn alloy containing 0.1 to 20 wt % of Zn, 0.1 to 3 wt % of Al, additionally containing totally 0.005 to 0.05 wt % of one or more elements selected from Ca, Be, and Si, and totally 0.1 to 3 wt % of one or more elements selected from Dy, La, Nd, Th, and Gd provide similar effects.

(E) Ag alloy reflection layers produced by sputtering using a target of Ag alloy containing both Cu and Ni, compared with Ag alloy reflection layers produced by sputtering using conventional Ag, Ag—Cu alloy, or Ag—Ni alloy targets, show little coarsening of crystal grains by repeated heating and cooling due to repeated incidence of a laser beam. Preferable composition of the Ag alloy containing both Cu and Ni comprises 0.5 to 5 wt % of Cu, 0.05 to 2 wt % of Ni, and a balance of Ag.

(F) Ag alloy reflection layers may be produced by sputtering using a target of Ag alloy containing 0.5 to 5 wt % of Cu, 0.05 to 2 wt % of Ni, totally 0.005 to 0.05 wt % of one or more elements selected from Ca, Be, and Si, and a balance of Ag. ln such Ag alloy reflection layers, coarsening of crystal grains by repeated heating and cooling due to repeated incidence of a laser beam is further reduced, and therefore, the layers show very little deterioration of reflectance after long-term use.

(G) Ag alloy reflection layers may be produced by sputtering using a target of Ag alloy containing 0.5 to 5 wt % of Cu, 0.05 to 2 wt % of Ni, additionally containing totally 0.1 to 3 wt % of one or more elements selected from Dy, La, Nd, Tb, and Gd and a balance of Ag. In such Ag alloy reflection layers, coarsening of crystal grains by repeated heating and cooling due to repeated incidence of a laser beam is further reduced, and therefore, the layers show very little deterioration of reflectance after long-term use.

(H) The similar effects can be achieved by Ag alloy reflection layers produced by sputtering using a target of Ag alloy containing 0.5 to 5 wt % of Cu, 0.05 to 2 wt % of Ni, totally 0.005 to 0.0 5 wt % of one or more elements selected from Ca, Be, and Si, and totally 0.1 to 3 wt % of one or more elements selected from Dy, La, Nd, Th, and Gd, and a balance of Ag.

Followings are the reason on which component of sputtering target for producing Ag alloy layers.

Zn:

Zn forms a solid solution with Ag in which Zn enhances the strength of the crystal gains; inhibits recrystallization of the crystal grains; and inhibits deterioration of reflectance of the reflection layers formed by sputtering. However, a Zn content of less than 0.1 wt % is insufficient to prevent the recrystallization of crystal grains, and is insufficient for inhibiting the deterioration of reflectance. Whereas, a Zn content of more than 20 wt % is not preferable. With such a content, Zn increases the internal strain of Ag alloy reflection layers formed by sputtering, and by forming a metallic compound within the crystal grains or in grain boundaries, cracking of a target is easily caused during its formation. Therefore, the Zn content included in the Ag alloy reflection layers, and sputtering targets for producing the alloy layers is controlled to be 0.1 to 20 wt %. Especially, to form full reflection layers, it is preferable to control the Zn content within a range from 1 to 20 wt %, more preferably, within a range from 5 to 15 wt %. To form semi-reflection layers, it is preferable to control Zn content within a range from 0.1 to less than 1 wt %, more preferably, within a range of 0.5 to 0.9 wt %.

Al:

Al forms a solid solution with Ag in which Al enhances the strength of the crystal grains; inhibits recrystallization of the crystal grains; and inhibits deterioration of reflectance of the reflection layers formed by sputtering. However, an Al content of less than 0.1 wt % is insufficient to prevent the recrystallization of crystal grains, and is insufficient for inhibiting the deterioration of reflectance. Whereas, an Al content of more than 3 wt % is not preferable. with such a content, Al increases the internal strain of Ag alloy reflection layers formed by sputtering, and enhance exfoliation of the reflection layers. Therefore, the Al content included in the Ag alloy reflection layers, and sputtering targets for producing the alloy layers is controlled to be 0.1 to 3 wt %. Especially, to form full reflection layers, it is preferable to control the Al content within a range from 0.5 to 3 wt %, more preferably, within a range from 1.0 to 2.0 wt %. To form semi-reflection layers, it is preferable to control the Al content within a range from 0.1 to less than 1 wt %, more preferably, within a range of 0.1 to 0.5 wt %.

Cu:

Cu forms a solid solution with Ag in which Cu enhances the strength of the crystal grains; inhibits recrystallization of crystal grains; and inhibits deterioration of reflectance of the reflection layers formed by sputtering. However, a Cu content of less than 0.5 wt % is insufficient to prevent the recrystallization of crystal grains, and is insufficient for restraining deterioration of reflectance. Whereas, a Cu content of more than 3 wt % is not preferable. With such a content, Cu increases the internal strain of Ag alloy reflection layers formed by sputtering, and enhance exfoliation of the reflection layers. Therefore, the Cu content included in the Ag alloy reflection layers, and sputtering targets for producing the alloy layers is controlled to be 0.5 to 5 wt %, more preferably, 1.0 to 3 wt %.

Ni:

Ni hardly forms a solid solution with Ag, and by precipitating at grain boundaries, prevents integration of crystal grains; inhibits recrystallization of crystal grains; and inhibits deterioration of reflectance of the reflection layers formed by sputtering. However, a Ni content of less than 0.05 wt % is insufficient to cause any effect Whereas, a Ni content of more than 2 wt % is not preferable. With such a content, Ni causes high film stress, and allows generation of cracking in films immediately after the sputtering. Therefore, the Ni content included in the Ag alloy reflection layers, and sputtering targets for producing the alloy layers is controlled to be 0.05 to 2 wt %, more preferably, 0.1 to 1.5 wt %.

Ca, Be, Si:

Since these elements are hardly soluble in Ag in a solid state, by precipitating at grain boundaries, these elements disturb integration of the crystal grains; and further restrict recrystallization of the crystal grains of the reflection layers. However, content of one or more of such elements show no prominent effect if their total content is less than 0.005 wt %. While, it is not preferable if the total content of one or more of such elements exceeds 0.05 wt %. Having such a content, a target is remarkably hardened, and therefore, cannot be effectively produced. Therefore, content of such elements in the Ag alloy reflection layer and sputtering targets for producing the Ag alloy reflection layers is controlled to be 0.005 to 0.05 wt %, more preferably, 0.010 to 0.035 wt %.

Dy, La, Nd, Th, Gd:

By reacting with Ag, these elements form intermetallic compounds at grain boundaries, and therefore disturb integration of the crystal grains; and further restrict recrystallization of the crystal grains of the reflection layers. However, content of one or more of such elements show no prominent effect if their total content is less than 0.1 wt %. While, it is not preferable if the total content of one or more of such elements exceeds 3 wt %. Having such a content, a target is remarkably hardened, and therefore, cannot be effectively produced. Therefore, content of such elements in Ag alloy reflection layer and sputtering targets for producing the Ag alloy reflection layers is controlled to be 0.1 to 3 wt %, more preferably, 0.2 to 1.5 wt %.

Compared to the reflection layers produced by a conventional Ag alloy sputtering target for reflection layers of the optical recording medium, reflection layers produced by Ag alloy spuring target for reflection layers of the optical recording medium according to the present invention have superior resistance to time-dependent deterioration, and enable the manufacture of optical recording mediums having a long lifetime, by which remarkable development of medium industry can be expected.

### EXAMPLES

[Experiment 1]

Ag, Zn, and Al, each having high purity of no less than 99.99 wt % were prepared as raw materials. The raw materials were melted in a radio frequency vacuum melting furnace. After melting the metal, Ar gas was introduced into the furnace to make an atmosphere inside the furnace have an ambient pressure. After that, ingots were obtained by casting molten metals in graphite molds. The ingots were heated at 600° C. for 2 hours and subsequently subjected to rolling and mechanical working. Thus, Examples 1 to 10, and Comparative Examples 1 to 2, and Conventional Examples 1 to 2 each having a diameter of 125 mm, thickness of 5 mm, and alloy composition listed in Table 1 were produced.

Examples 1 to 10, Comparative Examples 1 to 2, and Conventional Examples 1 to 2 were respectively soldered to backing plates made of oxygen-free copper. Each backing plate was mounted on a direct-current magnetron sputtering equipment By evacuation using a vacuum exhauster, atmospheric pressure inside the direct-current magnetron sputtering equipment was reduced to 1×10⁻⁴ Pa. After that, Ar gas was introduced into the sputtering equipment and a gas pressure of 1.0 Pa as a sputtering condition was obtained. Next, from a direct current power source, direct-current power of 100 W was applied to the target to generate a plasma between the target and a glass substrate which was placed opposite to the target in parallel arrangement with an intervening spacing of 70 mm. By such an experiment, on glass substrates of 30 mm in diameter, and 0.5 mm in thickness, Ag or Ag alloy full reflection films of 100 nm in thickness were formed.

Immediately after deposition of the Ag or Ag alloy full reflection films, reflectance of each film was measured using a spectrophotometer. Subsequently, the Ag or Ag alloy full reflection films were placed within a thermo-hygrostat at a temperature of 80° C., at a relative humidity of 85%, for 200 hours. After that treatment, reflectance of each film was measured under the same conditions. From the experimental results for reflectance, reflectances for wavelengths of 400 nm, and 650 nm were respectively determined and are listed in Table 1. From these data, durability of the Ag or Ag alloy films in data replaying was evaluated as reflection films of an optical recording medium.

TABLE 1

| | | | | | Reflectance | | Reflectance | | |
|---|---|---|---|---|---|---|---|---|---|
| | | | | | for wavelength: | | for wavelength: | | |
| | | | | | 400 nm | | 650 nm | | |
| | | Component | | | (%) | | (%) | | |
| | | (wt %) | | | As | After | As | After | |
| Target | | Zn | Al | Ag | formed | 200 hr | formed | 200 hr | Remark |
| Example | 1 | 1.2 | 0.51 | balance | 92 | 91 | 98 | 96 | — |
| | 2 | 4.6 | 1.0 | balance | 91 | 90 | 96 | 95 | — |
| | 3 | 6.5 | 1.5 | balance | 90 | 88 | 96 | 95 | — |
| | 4 | 8.1 | 2.1 | balance | 89 | 88 | 95 | 93 | — |
| | 5 | 9.9 | 2.5 | balance | 88 | 87 | 95 | 94 | — |
| | 6 | 11.5 | 3.0 | balance | 88 | 86 | 94 | 92 | — |
| | 7 | 13.3 | 0.50 | balance | 88 | 87 | 94 | 93 | — |
| | 8 | 14.8 | 1.0 | balance | 87 | 85 | 93 | 91 | — |
| | 9 | 17.4 | 2.0 | balance | 85 | 84 | 92 | 90 | — |
| | 10 | 19.8 | 2.9 | balance | 84 | 82 | 91 | 90 | — |
| Comparative | 1 | 23* | 1.5 | balance | — | — | — | — | cracking |
| Example | 2 | 10 | 4* | balance | — | — | — | — | exfoliation |
| Conventional | 1 | — | — | 100 | 93 | 41 | 99 | 77 | — |
| Example | 2 | 6.3 | — | balance | 90 | 75 | 97 | 85 | — |

As formed: immediately after film deposition
symbol * denotes values exceeding the range of the example

From the results listed in Table 1, it is obvious that the degree of deterioration of reflectance is smaller in full reflection layers formed by sputtering using targets of Examples 1 to 10 than in full reflection layers formed by sputtering using targets of Conventional Examples 1 to 2 after keeping the layers within a thermo-hygrostat at a temperature of 80° C., at a relative humidity of 85%, for 200 hours. Whereas, in Comparative Examples 1 to 2, in which Zn and Al contents exceeded the range of the Examples, occurrence of cracking or the like and reduction of durability as reflection films of an optical recording medium could not be avoided.

[Experiment 2]

Ca, Be, and Si, each having purity of no less than 99.9 wt % were prepared. Since Ca, Be, and Si are hardly soluble in Ag in a solid state, each elements are mixed with Ag so as to have a content of 0.20 wt %. Mixed metal was melted within a radio frequency vacuum furnace. After melting the metal, Ar gas was introduced into the furnace to make an atmosphere inside the furnace to have an ambient pressure. After that, master Ag alloys containing Ca, Be, and Si were obtained by casing molten metals in graphite molds.

By adding these master alloys to high purity Ag, Zn, and Al prepared in the first experiment, and by melting and casting the mixed metals, ingots were produced. The ingots were heated at 600° C. for 2 hours and subsequently subjected to rolling and mechanical working. Thus, Examples 11 to 28, and Comparative Examples 3 to 5, each having diameter of 125 mm, thickness of 5 mm, and alloy composition listed in Table 2 and 3 were produced.

Examples 11 to 28, and Comparative Examples 3 to 5 were respectively soldered to backing plates made of oxygen-free copper. Each backing plate was mounted on a direct-current magnetron sputtering equipment. By evacuation using a vacuum exhauster, atmospheric pressure inside the direct-current magnetron sputtering equipment was reduced to 1×10⁻⁴ Pa After that, Ar gas was introduced into the sputtering equipment and a gas pressure of 1.0 Pa as a sputtering condition was obtained. Next, from a direct current power source, direct-current power of 100 W was applied to the target to generate a plasma between the target and a glass substrate which was placed opposite to the target in parallel arrangement with an intervening spacing of 70 mm. By such an experiment, on glass substrates of 30 mm in diameter, and 0.5 mm in thickness, Ag or Ag alloy fill reflection films of 100 nm in thickness were formed.

Immediately after deposition of the Ag or Ag alloy full reflection films, reflectance of each film was measured using a spectrophotometer. Subsequently, the Ag Or Ag alloy full reflection films were placed within a thermo-hygrostat and kept at a temperature of 80° C., at a relative humidity of 85%, for 200 hours. Afer that treatment, reflectance of the films was measured under the same conditions. From the experimental results for reflectance, reflectances for wavelength of 400 nm, and 650 nm were respectively determined and are listed in Tables 2 and 3. From these data, durability of the Ag or Ag alloy films in data replaying was evaluated as reflection films of optical recording medium.

TABLE 2

| | | | | | | | | Reflectance | | Reflectance | |
|---|---|---|---|---|---|---|---|---|---|---|---|
| | | | | | | | | for wavelength: | | for wavelength: | |
| | | | | | | | | 400 nm | | 650 nm | |
| | | | | | | | | (%) | | (%) | |
| | | Component (wt %) | | | | | | As | After | As | Afetr |
| Target | | Zn | Al | Ca | Be | Si | Ag | formed | 200 hr | formed | 200 hr |
| Ex. | 11 | 10.0 | 1.0 | 0.005 | — | — | balance | 88 | 87 | 95 | 94 |
| | 12 | 10.2 | 1.5 | 0.012 | — | — | balance | 87 | 85 | 94 | 93 |
| | 13 | 10.2 | 2.0 | 0.030 | — | — | balance | 85 | 84 | 93 | 92 |
| | 14 | 10.1 | 1.0 | 0.049 | — | — | balance | 84 | 83 | 93 | 91 |
| | 15 | 10.1 | 1.6 | — | 0.005 | — | balance | 88 | 87 | 94 | 93 |
| | 16 | 10.0 | 1.9 | — | 0.015 | — | balance | 87 | 85 | 94 | 92 |
| | 17 | 10.2 | 1.0 | — | 0.048 | — | balance | 84 | 82 | 93 | 92 |
| | 18 | 10.1 | 1.6 | — | — | 0.006 | balance | 88 | 87 | 94 | 93 |
| | 19 | 10.1 | 2.0 | — | — | 0.021 | balance | 86 | 85 | 94 | 93 |
| | 20 | 10.3 | 1.0 | — | — | 0.049 | balance | 84 | 83 | 93 | 92 |
| | 21 | 10.3 | 1.5 | 0.003 | 0.002 | — | balance | 88 | 86 | 94 | 92 |
| | 22 | 10.0 | 2.0 | 0.003 | 0.045 | — | balance | 84 | 82 | 93 | 91 |
| | 23 | 10.1 | 0.9 | — | 0.001 | 0.004 | balance | 88 | 87 | 95 | 94 |
| | 24 | 10.2 | 1.5 | — | 0.025 | 0.024 | balance | 84 | 83 | 93 | 92 |

Ex.: Example

TABLE 3

| | | | | | | | | Reflectance | | Reflectance | | |
|---|---|---|---|---|---|---|---|---|---|---|---|---|
| | | | | | | | | for | | for | | |
| | | | | | | | | WL: 400 nm | | WL: 650 nm | | |
| | | | | | | | | (%) | | (%) | | |
| | | Component (wt %) | | | | | | As | After | As | After | |
| Target | | Zn | Al | Ca | Be | Si | Ag | formed | 200 hr | formed | 200 hr | Remark |
| EX. | 25 | 10.1 | 2.0 | 0.002 | — | 0.003 | balance | 88 | 86 | 94 | 92 | — |
| | 26 | 10.2 | 1.0 | 0.024 | — | 0.024 | balance | 84 | 82 | 93 | 91 | — |
| | 27 | 10.1 | 1.5 | 0.001 | 0.001 | 0.003 | balance | 88 | 86 | 94 | 93 | — |
| | 28 | 10.1 | 1.9 | 0.013 | 0.013 | 0.020 | balance | 84 | 83 | 93 | 92 | — |
| COMP. | 3 | 10.0 | 1.0 | 0.06* | — | — | balance | — | — | — | — | Not |
| EX. | | | | | | | | | | | | formed |
| | 4 | 10.1 | 1.5 | — | 0.06* | — | balance | — | — | — | — | Not |
| | | | | | | | | | | | | formed |
| | 5 | 10.0 | 2.0 | — | — | 0.06* | balance | — | — | — | — | Not |
| | | | | | | | | | | | | formed |

symbol * denotes values exceeding the range of the example
Ex: Example
COMP. EX.: Comparative Example
WL: wavelength

From the results listed in Table 2 and 3, it is obvious that the degree of deterioration of reflectance is smaller in fill reflection layers formed by sputtering using targets of Examples 11 to 28 than in full reflection layers formed by sputtering using targets of Conventional Examples 1 to 2 listed in Table 1 of the Experiment 1 after keeping the layers within a thermo-hygrostat at a temperature of 80° C., at a relative humidity of 85%, for 200 hours. Whereas, in Comparative Examples 3 to 5, in which Ca, Be, and Si contents exceeded the range of the present invention, targets could not be formed because of their hardness.

[Experiment 3]

Dy, La, Nd, Td, and Gd each having purity of no less than 99.9 wt % were prepared. These raw materials were added to highly pure Ag, Zn, and Al prepared in the first experiment, and melted within a radio frequency vacuum furnace. Ingots were produced by casting the molten metals in graphite molds under Ar gas atmosphere. The ingots were heated at 600° C. for 2 hours and subsequently subjected to rolling and mechanical working. Thus, Examples 29 to 53, and Comparative Examples 6 to 11, each having a diameter of 125 mm, thickness of 5 mm, and alloy composition listed in Table 4 to 6 were produced.

Examples 29 to 53, and Comparative Examples 6 to 11 were respectively soldered to backing plates made of oxygen-free copper. Each backing plate was mounted on a direct-current magnetron sputtering equipment. By evacuation using a vacuum exhauster, atmospheric pressure inside the direct-current magnetron sputtering equipment was reduced to 1×10⁻⁴ Pa. After that, Ar gas was introduced into the sputtering equipment and a gas pressure of 1.0 Pa as a sputtering condition was obtained. Next, from a direct current power source, direct-current power of 100 W was applied to the target to generate a plasma between the target and a glass substrate which was placed opposite to the target in parallel arrangement with an intervening spacing of 70 mm. By such an experiment, on glass substrates of 30 mm in diameter, and 0.5 mm in thickness, Ag alloy full reflection films of 100 nm in thickness were formed.

Immediately after deposition of the Ag alloy full reflection films, reflectance of each film was measured using a spectrophotometer. Subsequently, the Ag alloy full reflection films were placed within a thermo-hygrostat and kept at a temperature of 80° C., at a relative humidity of 85%, for 200 hours. After that treatment, reflectance of each film was measured under the same conditions. From the experimental data for reflectance, reflectances for wavelengths of 400 nm, and 650 nm were respectively determined and are listed in Tables 4 to 6. From these data, durability of each Ag alloy film in data replaying was evaluated as full reflection film of an optical recording medium.

TABLE 4

| | | | | | | | | | | Reflectance | | Reflectance | |
|---|---|---|---|---|---|---|---|---|---|---|---|---|---|
| | | | | | | | | | | for | | for | |
| | | | | | | | | | | WL: 400 nm | | WL: 650 nm | |
| | | | | | | | | | | (%) | | (%) | |
| | | Component (wt %) | | | | | | | | As | After | As | After |
| Target | | Zn | Al | Dy | La | Nd | Tb | Gd | Ag | formed | 200 hr | formed | 200 hr |
| Ex. | 29 | 10.1 | 1.5 | 0.11 | — | — | — | — | balance | 88 | 87 | 95 | 94 |
| | 30 | 10.0 | 1.5 | 1.02 | — | — | — | — | balance | 86 | 85 | 93 | 92 |
| | 31 | 10.2 | 1.5 | 2.10 | — | — | — | — | balance | 83 | 82 | 91 | 90 |
| | 32 | 10.0 | 1.6 | 2.99 | — | — | — | — | balance | 81 | 80 | 90 | 89 |
| | 33 | 10.1 | 1.5 | — | 0.10 | — | — | — | balance | 88 | 86 | 95 | 93 |
| | 34 | 10.2 | 1.6 | — | 1.01 | — | — | — | balance | 86 | 85 | 93 | 92 |
| | 35 | 10.0 | 1.6 | — | 2.00 | — | — | — | balance | 84 | 82 | 92 | 90 |
| | 36 | 10.0 | 1.5 | — | 2.98 | — | — | — | balance | 82 | 81 | 90 | 88 |
| | 37 | 10.3 | 1.5 | — | — | 0.11 | — | — | balance | 88 | 87 | 94 | 93 |
| | 38 | 10.1 | 1.5 | — | — | 1.10 | — | — | balance | 86 | 85 | 93 | 92 |
| | 39 | 10.2 | 1.5 | — | — | 2.09 | — | — | balance | 83 | 81 | 92 | 90 |
| | 40 | 10.1 | 1.6 | — | — | 2.90 | — | — | balance | 81 | 80 | 90 | 89 |
| | 41 | 10.0 | 1.6 | — | — | — | 0.12 | — | balance | 88 | 87 | 95 | 93 |
| | 42 | 10.1 | 1.5 | — | — | — | 0.11 | — | balance | 85 | 84 | 93 | 92 |

TABLE 5

| | | | | | | | | | | Reflectance | | Reflectance | |
|---|---|---|---|---|---|---|---|---|---|---|---|---|---|
| | | | | | | | | | | for | | for | |
| | | | | | | | | | | WL: 400 nm | | WL: 650 nm | |
| | | | | | | | | | | (%) | | (%) | |
| | | Component (wt %) | | | | | | | | As | After | As | After |
| Target | | Zn | Al | Dy | La | Nd | Tb | Gd | Ag | formed | 200 hr | formed | 200 hr |
| Ex. | 43 | 10.1 | 1.6 | — | — | — | 2.10 | — | balance | 82 | 80 | 92 | 91 |
| | 44 | 10.0 | 1.5 | — | — | — | 2.97 | — | balance | 80 | 79 | 90 | 88 |
| | 45 | 10.2 | 1.5 | — | — | — | — | 0.11 | balance | 88 | 86 | 94 | 93 |
| | 46 | 10.0 | 1.6 | — | — | — | — | 0.99 | balance | 86 | 84 | 93 | 92 |
| | 47 | 10.0 | 1.6 | — | — | — | — | 2.01 | balance | 83 | 82 | 92 | 90 |
| | 48 | 10.1 | 1.5 | — | — | — | — | 2.89 | balance | 81 | 80 | 90 | 89 |
| | 49 | 10.1 | 1.5 | 0.05 | 0.05 | — | — | — | balance | 88 | 87 | 95 | 93 |
| | 50 | 10.1 | 1.5 | 1.02 | 1.20 | — | — | — | balance | 83 | 81 | 91 | 90 |
| | 51 | 10.0 | 1.5 | — | — | 0.11 | 1.13 | 1.52 | balance | 81 | 80 | 91 | 89 |
| | 52 | 10.2 | 1.6 | 0.91 | 0.57 | 1.01 | — | 1.00 | balance | 80 | 79 | 89 | 88 |
| | 53 | 10.1 | 1.5 | 0.58 | 0.57 | 0.61 | 0.62 | 0.61 | balance | 81 | 79 | 90 | 88 |

TABLE 6

| | | | | | | | | | | Reflectance | | Reflectance | | |
|---|---|---|---|---|---|---|---|---|---|---|---|---|---|---|
| | | | | | | | | | | for | | for | | |
| | | | | | | | | | | WL: 400 nm | | WL: 650 nm | | |
| | | | | | | | | | | (%) | | (%) | | |
| | | Component (wt %) | | | | | | | | As | After | As | After | |
| Target | | Zn | Al | Dy | La | Nd | Tb | Gd | Ag | formed | 200 hr | formed | 200 hr | Remark |
| COMP. | 6 | 10.2 | 1.5 | 3.3* | — | — | — | — | balance | — | — | — | — | Not formed |
| EX. | 7 | 10.0 | 1.5 | — | 3.4* | — | — | — | balance | — | — | — | — | Not formed |
| | 8 | 10.0 | 1.5 | — | — | 3.3* | — | — | balance | — | — | — | — | Not formed |
| | 9 | 10.1 | 1.6 | — | — | — | 3.4* | — | balance | — | — | — | — | Not formed |
| | 10 | 10.0 | 1.5 | — | — | — | — | 3.5* | balance | — | — | — | — | Not formed |
| | 11 | 10.1 | 1.5 | 1.01 | 1.02 | 0.55 | 0.51 | 0.12 | balance | — | — | — | — | Not formed |

From the results listed in Table 4 to 6, it is obvious that the degree of deterioration of reflectance is smaller in full reflection layers formed by sputtering using targets of Examples 29 to 53 than in full reflection layers formed by sputtering using targets of Conventional Examples 1 to 2 listed in Table 1 of Experiment 1 after keeping the layers within a thermo-hygrostat at a temperature of 80° C., at a relative humidity of 85%, for 200 hours. Whereas, as shown in Comparative Examples 6 to 11, Ag alloy containing Dy, La, Nd, Tb, and Gd totally more than 3 wt % could not be formed, for example, due to generation of cracking during the rolling.

[Experiment 4]

Highly pure Ag, Zn, and Al prepared in Experiment 1, Ca, Be, and master Ag alloy containing Si prepared in Experiment 2, and Dy, La, Nd, Td, and Gd prepared in Experiment 3 were melted within a radio frequency vacuum furnace. Ingots were produced by casting the molten metals in graphite molds under Ar gas atmosphere. The ingots were heated at 600° C. for 2 hours and subsequently subjected to rolling and mechanical working. Thus, Examples 54 to 65 each having a diameter of 125 mm, thickness of 5 mm, and alloy composition listed in Table 7 were produced. Using these targets Ag alloy full reflection films of 100 nm in thickness were produced on surfaces of glass substrates by a same procedure as Experiment 1. Immediately after deposition of the Ag alloy full reflection films, reflectance of the films were measured using a spectrophotometer. Subsequently, the Ag alloy full reflection films were placed within a thermo-hygrostat and kept at a temperature of 80° C., at a relative humidity of 85%, for 200 hours. After that treatment, reflectance of the films were measured under the same condition. From the experimental data for reflectance, reflectances for wavelengths of 400 nm, and 650 nm were respectively determined and are listed in Table 7. From these data, durability of the Ag alloy full reflection films in data replaying were evaluated as reflection films of an optical recording medium.

TABLE 7

| | | | | | | | | Reflectance | | Reflectance | |
|---|---|---|---|---|---|---|---|---|---|---|---|
| | | | | | | | | for | | for | |
| | | | | | | | | WL: 400 nm | | WL: 650 nm | |
| | | | | | | | | (%) | | (%) | |
| | | Component (wt %) | | | | | | As | After | As | After |
| Target | | Zn | Al | Ca, Be, Si | Dy, La, Nd, Tb, Gd | | Ag | formed | 200 hr | formed | 200 hr |
| Ex. | 54 | 10.2 | 1.6 | Ca: 0.011 | Dy: 0.21 | | balance | 87 | 85 | 94 | 93 |
| | 55 | 10.1 | 1.5 | Be: 0.021 | La: 0.50 | | balance | 85 | 84 | 93 | 92 |
| | 56 | 10.1 | 1.5 | Si: 0.030 | Nd: 0.82 | | balance | 83 | 82 | 92 | 90 |
| | 57 | 10.3 | 1.5 | Ca: 0.011 | Tb: 1.00 | | balance | 82 | 80 | 92 | 91 |
| | | | | Si: 0.020 | | | | | | | |
| | 58 | 10.0 | 1.5 | Be: 0.029 | Gd: 1.49 | | balance | 82 | 81 | 91 | 90 |
| | 59 | 10.0 | 1.6 | Si: 0.025 | Dy: 0.05 | Gd: 0.06 | balance | 86 | 85 | 93 | 91 |
| | 60 | 10.1 | 1.6 | Ca: 0.014 | La: 0.06 | Tb: 0.12 | balance | 85 | 83 | 93 | 92 |
| | | | | Be. 0015 | | | | | | | |
| | 61 | 10.2 | 1.6 | Be: 0.031 | Nd: 0.51 | Dy: 0.52 | balance | 83 | 82 | 92 | 91 |
| | 62 | 10.0 | 1.5 | Si: 0.028 | Tb: 1.01 | Nd: 1.05 | balance | 80 | 78 | 90 | 89 |
| | 63 | 10.0 | 1.5 | Ca: 0.025 | Gd: 1.45 | La: 1.46 | balance | 79 | 78 | 89 | 87 |
| | 64 | 10.3 | 1.5 | Be: 0.015 | Dy: 0.05 | Gd.0.07 | balance | 85 | 83 | 93 | 92 |
| | | | | Si: 0.011 | Nd: 0.12 | | | | | | |
| | 65 | 10.1 | 1.5 | Si: 0.025 | La: 0.61 | Tb: 0.57 | balance | 78 | 77 | 89 | 88 |
| | | | | | Dy: 0.63 | Nd: 0.59 | | | | | |
| | | | | | Gd: 0.55 | | | | | | |

From the results listed in Table 7, it is obvious that the degree of deterioration of reflectance is smaller in full reflection layers formed by sputtering using targets of Examples 54 to 65 than in fill reflection layers formed by sputtering using targets of Conventional Examples 1 to 2 listed in Table 1 after keeping the layers within a at a temperature of 80° C., at a relative humidity of 85%, for 200 hours.

[Experiment 5]

Examples 66 to 93 and Comparative Examples 12 to 14 each having a composition listed in Tables 8 to 10 were produced in a same manner as in Experiments 1 and 2. In addition, Conventional Examples 1 to 2 produced in Experiment 1 were also prepared.

Examples 66 to 93, Comparative Examples 12 to 14, and Conventional Examples 1 to 2 were respectively soldered to backing plates made of oxygen-free copper. Each backing plate was mounted on a direct-current magnetron sputtering equipment By evacuation using a vacuum exhauster, atmospheric pressure inside the direct-current magnetron sputtering equipment was reduced to 1×10⁻⁴ Pa. After that, Ar gas was introduced into the sputtering equipment and a gas pressure of 1.0 Pa as a sputtering condition was obtained, Next from a direct current power source, direct-current power of 100 W for sputtering was applied to the target to generate a plasma between the target and a glass substrate which was placed opposite to the target in a parallel arrangement with an intervening spacing of 70 mm. By such a experiment, on glass substrates of 30 mm in diameter, and 0.5 mm in thickness, Ag or Ag alloy semi-reflection films of 10 nm in thickness were formed.

Immediately after deposition of the Ag or Ag alloy semi-reflection film, reflectance and transmittances of the films were measured using a spectrophotometer. From a spectral reflectance curve and spectral transmittance curve measured in a range of wavelengths from 300 to 800 nm, reflectance and transmittance for wavelength of 405 nm were respectively determined and are listed in Tables 8 to 10.

Subsequently, the Ag or Ag alloy semi-reflection films were placed within a and kept at a temperature of 80° C., at a relative humidity of 85%, for 200 hours. After that treatment, reflectance and transmittance of the films were measured under the same conditions, and the results are listed in Tables 8 to 10. From the experimental results for reflectance and transmittance of the semi-reflection films immediately after the deposition, absorbance of the semi-reflection films for a laser beam of 405 nm wavelength was calculated and is listed in Tables 8 to 10. From the reflectance and transmittance of the semi-reflection films after being kept at a temperature of 80° C., at a relative humidity of 85%, for 200 hours, absorbance of the semi-reflection films for laser beam of 405 nm wavelength after the 200 hr treatment was calculated and is listed in Tables 8 to 10.

TABLE 8

| | | | | | | | | As formed | | | After 200 hr | | |
|---|---|---|---|---|---|---|---|---|---|---|---|---|---|
| | | Component (wt %) | | | | | | Refl | Trans | Abs | Refl | Trans | Abs |
| Target | | Zn | Al | Ca | Be | Si | Ag | (%) | (%) | (%) | (%) | (%) | (%) |
| Ex. | 66 | 0.10 | 0.11 | — | — | — | balance | 29 | 69 | 2 | 27 | 68 | 5 |
| | 67 | 0.22 | 0.20 | — | — | — | balance | 28 | 69 | 3 | 27 | 69 | 4 |
| | 68 | 0.31 | 0.30 | — | — | — | balance | 26 | 71 | 3 | 26 | 69 | 5 |
| | 69 | 0.51 | 0.39 | — | — | — | balance | 28 | 70 | 2 | 27 | 68 | 5 |
| | 70 | 0.72 | 0.10 | — | — | — | balance | 26 | 72 | 2 | 25 | 71 | 4 |
| | 71 | 0.95 | 0.21 | — | — | — | balance | 25 | 72 | 3 | 24 | 71 | 5 |
| | 72 | 0.55 | 0.31 | — | — | — | balance | 25 | 70 | 5 | 24 | 69 | 7 |
| | 73 | 0.70 | 0.40 | — | — | — | balance | 24 | 70 | 6 | 24 | 68 | 8 |
| | 74 | 0.90 | 0.10 | — | — | — | balance | 26 | 71 | 3 | 24 | 71 | 5 |
| | 75 | 0.91 | 0.25 | — | — | — | balance | 24 | 72 | 4 | 24 | 70 | 6 |
| | 76 | 0.10 | 0.11 | 0.005 | — | — | balance | 28 | 70 | 2 | 27 | 70 | 3 |
| | 77 | 0.22 | 0.20 | 0.012 | — | — | balance | 27 | 71 | 2 | 26 | 71 | 3 |
| | 78 | 0.31 | 0.30 | 0.030 | — | — | balance | 26 | 72 | 2 | 26 | 72 | 2 |
| | 79 | 0.51 | 0.40 | 0.049 | — | — | balance | 27 | 71 | 2 | 27 | 70 | 3 |

Refl: Reflectance
Trans: Transmittance
Abs: Absorbance of film

TABLE 9

| | | | | | | | | As formed | | | After 200 hr | | |
|---|---|---|---|---|---|---|---|---|---|---|---|---|---|
| | | Component (wt %) | | | | | | Refl | Trans | Abs | Refl | Trans | Abs |
| Target | | Zn | Al | Ca | Be | Si | Ag | (%) | (%) | (%) | (%) | (%) | (%) |
| Ex. | 80 | 0.72 | 0.10 | — | 0.005 | — | balance | 26 | 73 | 1 | 25 | 73 | 2 |
| | 81 | 0.95 | 0.20 | — | 0.015 | — | balance | 23 | 74 | 3 | 23 | 73 | 4 |
| | 82 | 0.55 | 0.30 | — | 0.048 | — | balance | 24 | 72 | 4 | 23 | 72 | 5 |
| | 83 | 0.70 | 0.40 | — | — | 0.006 | balance | 24 | 70 | 6 | 24 | 71 | 5 |
| | 84 | 0.90 | 0.10 | — | — | 0.021 | balance | 24 | 73 | 3 | 24 | 73 | 3 |
| | 85 | 0.90 | 0.25 | — | — | 0.049 | balance | 21 | 74 | 5 | 21 | 74 | 5 |
| | 86 | 0.10 | 0.10 | 0.003 | 0.002 | — | balance | 28 | 69 | 3 | 29 | 69 | 2 |
| | 87 | 0.22 | 0.20 | 0.003 | 0.045 | — | balance | 25 | 72 | 3 | 26 | 71 | 3 |
| | 88 | 0.31 | 0.30 | — | 0.001 | 0.004 | balance | 26 | 70 | 4 | 26 | 71 | 3 |
| | 89 | 0.51 | 0.40 | — | 0.025 | 0.024 | balance | 20 | 74 | 6 | 20 | 74 | 6 |
| | 90 | 0.72 | 0.10 | 0.002 | — | 0.003 | balance | 26 | 72 | 2 | 26 | 72 | 2 |
| | 91 | 0.95 | 0.21 | 0.024 | — | 0.024 | balance | 24 | 72 | 4 | 23 | 72 | 5 |
| | 92 | 0.55 | 0.31 | 0.001 | 0.001 | 0.003 | balance | 23 | 74 | 3 | 24 | 73 | 3 |
| | 93 | 0.70 | 0.39 | 0.013 | 0.013 | 0.020 | balance | 22 | 74 | 4 | 23 | 72 | 5 |

TABLE 10

| | | | | | | | | As formed | | | After 200 hr | | |
|---|---|---|---|---|---|---|---|---|---|---|---|---|---|
| | | Component (wt %) | | | | | | Refl | Trans | Abs | Refl | Trans | Abs |
| Target | | Zn | Al | Ca | Be | Si | Ag | (%) | (%) | (%) | (%) | (%) | (%) |
| COMP. | 12 | 0.07* | 0.10 | — | — | — | balance | 29 | 70 | 1 | 17 | 72 | 11 |
| EX. | 13 | 10 | 0.07* | — | — | — | balance | 20 | 45 | 35 | 14 | 47 | 39 |
| | 14 | 0.05* | 0.06* | — | — | — | balance | 29 | 70 | 1 | 18 | 71 | 11 |
| CONV. | 1 | — | — | — | — | — | 100 | 32 | 40 | 28 | 20 | 42 | 38 |
| EX. | 2 | 6.3 | — | — | — | — | balance | 22 | 47 | 31 | 15 | 48 | 37 |

COMP. EX: Comparative Example
CONV. EX.: Conventional Example

From the results listed in Tables 8 to 10, it is obvious that the degree of deterioration of reflectance is smaller in semi-reflection layers formed by sputtering using targets of Examples 66 to 93 than in semi-reflection layers formed by sputtering using targets of Conventional Examples 1 to 2 after keeping the layers within a thermo-hygrostat at a temperature of 80° C., at a relative humidity of 85%, for 200 hours. With regard to the absorbance for a laser beam of the films calculated from the reflectance and transmittance, increase of absorbance is smaller in Examples 66 to 93 than in Conventional Examples 1 and 2 after keeping the films within a thermo-hygrostat at a temperature of 80° C., at a relative humidity of 85%, for 200 hours. Whereas, Comparative Examples 12 to 14, in which Zn and Al content exceeded the range of the present invention, show reduction of reflectance and transmittance, and therefore are not preferable as a semi-reflection film of an optical recording medium. Moreover, the Comparative Examples 12 to 14 show prominent increase in absorbance after the treatment within the thermo-hygrostat at a temperature of 80° C., at a relative humidity of 85%, for 200 hours.

[Experiment 6]

Ag and Cu each having high purity of no less than 99.99 wt % were prepared as raw materials. Since Ni is hardly soluble in Ag in a solid state, master Cu alloy containing Ni was preliminarily prepared as a raw material for Ni by melting Cu added with Ni within a radio frequency vacuum furnace, and casting the molten metal in a graphite mold. The prepared Ag, Cu, and master Cu alloy containing Ni were melted in a radio frequency vacuum furnace, and the molten metals were cast in graphite molds under Ar gas atmosphere, and thereby ingots were produced. The ingots were heated at 600° C. for 2 hours and subsequently subjected to rolling and mechanical working. Thus, Examples 94 to 102, Comparative Examples 15 to 17, and Conventional Examples 3 to 4 each having a diameter of 125 mm, thickness of 5 mm, and alloy composition listed in Table 11 were produced.

Examples 94 to 102, Comparative Examples 15 to 17, and Conventional Examples 3 to 4 were respectively soldered to backing plates made of oxygen-free copper. Each backing plate was mounted on a direct-current magnetron sputtering equipment. By evacuation using a vacuum exhauster, atmospheric pressure inside the direct-current magnetron sputtering equipment was reduced to 1×10⁻⁴ Pa. After that, Ar gas was introduced into the sputtering equipment and a gas pressure of 1.0 Pa as a sputtering condition was obtained. Next, from a direct current power source, direct-current power of 100 W was applied to the target to generate a plasma between the target and a glass substrate which was placed opposite to the target in a parallel arrangement with an intervening spacing of 70 mm. By such an experiment, on glass substrates of 30 mm in diameter, and 0.5 mm in thickness, Ag alloy reflection films of 100 nm in thickness were formed.

Immediately after deposition of the Ag alloy reflection films, reflectance of each film was measured using a spectrophotometer. Subsequently, the Ag alloy reflection films were placed within a thermo-hygrostat at a temperature of 80° C., at a relative humidity of 85%, for 200 hours. After that teatment, reflectance of each film was measured under the same condition. From the experimental results for reflectance, reflectances for wavelength of 400 nm, and 650 nm were respectively determined and listed in Table 11. From these data, durability of the Ag alloy reflection films in data replaying were evaluated as reflection films of an optical recording medium.

TABLE 11

| | | | | | Reflectance | | Reflectance | |
|---|---|---|---|---|---|---|---|---|
| | | | | | for | | for | |
| | | | | | WL: 400 nm | | WL: 650 nm | |
| | | | | | (%) | | (%) | |
| | | Component (wt %) | | | | After | | After |
| Target | | Cu | Ni | Ag | As formed | 200 hr | As formed | 200 hr |
| Example | 94 | 0.51 | 1.93 | balance | 86 | 84 | 96 | 95 |
| | 95 | 1.03 | 1.11 | balance | 86 | 84 | 97 | 96 |
| | 96 | 1.52 | 0.15 | balance | 87 | 86 | 97 | 96 |
| | 97 | 2.00 | 0.64 | balance | 85 | 83 | 96 | 94 |
| | 98 | 3.00 | 0.32 | balance | 84 | 83 | 96 | 95 |
| | 99 | 4.05 | 0.11 | balance | 82 | 80 | 95 | 93 |
| | 100 | 5.00 | 0.05 | balance | 80 | 78 | 94 | 92 |
| | 101 | 2.01 | 0.89 | balance | 85 | 84 | 97 | 96 |
| | 102 | 2.83 | 0.25 | balance | 84 | 83 | 96 | 85 |
| Comparative | 15 | 0.35* | 0.01* | balance | 89 | 68 | 99 | 84 |
| Example | 16 | 5.5* | 0.15 | balance | 79 | 57 | 93 | 81 |
| | 17 | 3.4 | 2.31* | balance | 80 | 56 | 93 | 78 |
| Conventional | 3 | — | — | 100 | 93 | 41 | 99 | 77 |
| Example | 4 | 5.6* | — | balance | 79 | 57 | 93 | 79 |

symbol * denotes values exceeding the range of the example

From the results listed in Table 11, it is obvious that the degree of deterioration of reflectance is smaller in reflection layers formed by sputtering using targets of examples 94 to 102 than in reflection layers formed by sputtering using targets of Comparative Examples 15 to 17 and Conventional Examples 3 to 4 after keeping the layers within a thermo-hygrostat at a temperature of 80° C., at a relative humidity of 85%, for 200 hours.

[Experiment 7]

Ca, Be, and Si, each having purity of no less than 99.9 wt % were prepared as raw materials. Since Ca, Be, and Si are hardly soluble in Ag in a solid state, each element was mixed with Ag so as to have a content of 0.20 wt %. Mixed metals were melted within a radio frequency vacuum furnace. After melting the metal, Ar gas was introduced into the furnace to make an atmosphere inside the furnace to have an ambient pressure. After that, by casting the molten metal in graphite molds, master Ag alloys containing Ca, Be, or Si were formed preliminarily.

These master alloys were added to Ag, together with Cu and the Ni bearing master Cu alloy prepared in Experiment 6. By melting and casting the mixed metals, ingots were produced. The ingots were heated at 600° C. for 2 hours and subsequently subjected to rolling and mechanical working. Thus, Examples 103 to 120, each having a diameter of 125 mm, thickness of 5 mm, and alloy composition listed in Tables 12 and 13 were produced.

Using the Examples 103 to 120, Ag alloy reflection films of 100 nm in thickness were prepared on surfaces of glass substrates in a same manner as Experiment 6. Immediately after deposition of the Ag alloy reflection films, reflectance of each film was measured using a speetrophotometer. Subsequently, the Ag alloy reflection films were placed within a thermo-hygrostat and kept at a temperature of 80° C., at a relative humidity of 85%, for 200 hours. Aft that treatment, reflectance of each film was measured under the same condition. From the experimental results for reflectance, reflectances for wavelength of 400 nm, and 650 nm were respectively determined and listed in Table 12 to 13. From these data, durability of the reflection films in data replaying were evaluated as reflection films of an optical recording medium.

TABLE 12

| | | | | | | | | Reflectance | | Reflectance | |
|---|---|---|---|---|---|---|---|---|---|---|---|
| | | | | | | | | for | | for | |
| | | | | | | | | WL: 400 nm | | WL: 650 nm | |
| | | | | | | | | (%) | | (%) | |
| | | Component (wt %) | | | | | | As | After | As | After |
| Target | | Cu | Ni | Ca | Be | Si | Ag | formed | 200 hr | formed | 200 hr |
| Ex. | 103 | 1.50 | 0.52 | 0.005 | — | — | balance | 86 | 84 | 97 | 95 |
| | 104 | 1.51 | 0.52 | 0.012 | — | — | balance | 85 | 84 | 96 | 94 |
| | 105 | 1.50 | 0.50 | 0.030 | — | — | balance | 83 | 82 | 96 | 94 |
| | 106 | 1.50 | 0.50 | 0.049 | — | — | balance | 81 | 80 | 95 | 94 |
| | 107 | 1.50 | 0.53 | — | 0.005 | — | balance | 86 | 85 | 97 | 95 |
| | 108 | 1.51 | 0.50 | — | 0.015 | — | balance | 85 | 83 | 96 | 95 |
| | 109 | 1.50 | 0.55 | — | 0.048 | — | balance | 81 | 80 | 95 | 93 |
| | 110 | 1.50 | 0.50 | — | — | 0.006 | balance | 86 | 84 | 97 | 95 |
| | 111 | 1.51 | 0.52 | — | — | 0.021 | balance | 84 | 83 | 96 | 95 |
| | 112 | 1.50 | 0.51 | — | — | 0.049 | balance | 81 | 80 | 95 | 94 |
| | 113 | 1.50 | 0.53 | 0.003 | 0.002 | — | balance | 86 | 84 | 96 | 94 |
| | 114 | 1.51 | 0.50 | 0.003 | 0.045 | — | balance | 81 | 80 | 94 | 92 |
| | 115 | 1.50 | 0.51 | — | 0.001 | 0.004 | balance | 86 | 84 | 97 | 95 |
| | 116 | 1.50 | 0.52 | — | 0.025 | 0.024 | balance | 81 | 79 | 95 | 93 |

TABLE 13

| | | | | | | | | Reflectance | | Reflectance | | |
|---|---|---|---|---|---|---|---|---|---|---|---|---|
| | | | | | | | | for | | for | | |
| | | | | | | | | WL: 400 nm | | WL: 650 nm | | |
| | | | | | | | | (%) | | (%) | | |
| | | Component (wt %) | | | | | | As | | As | After | |
| Target | | Cu | Ni | Ca | Be | Si | Ag | formed | 200 hr | formed | 200 hr | Remark |
| Ex. | 117 | 1.51 | 0.52 | 0.002 | — | 0.003 | balance | 86 | 85 | 96 | 95 | — |
| | 118 | 1.50 | 0.53 | 0.024 | — | 0.024 | balance | 86 | 84 | 97 | 95 | — |
| | 119 | 1.50 | 0.50 | 0.001 | 0.001 | 0.003 | balance | 85 | 84 | 97 | 96 | — |
| | 120 | 1.50 | 0.50 | 0.013 | 0.013 | 0.020 | balance | 86 | 85 | 97 | 95 | — |
| COMP. | 18 | 2.01 | 0.59 | 0.004 | 0.011 | 0.051* | balance | — | — | — | — | Not |
| EX. | | | | | | | | | | | | formed |
| | 19 | 2.04 | 0.63 | 0.06* | — | — | balance | — | — | — | — | Not |
| | | | | | | | | | | | | formed |
| | 20 | 2.03 | 0.61 | — | 0.06* | — | balance | — | — | — | — | Not |
| | | | | | | | | | | | | formed |
| | 21 | 2.01 | 0.62 | — | — | 0.06* | balance | — | — | — | — | Not |
| | | | | | | | | | | | | formed |

symbol * denotes values exceeding the range of the example

From the results listed in Table 12 and 13, it is obvious that the degree of deterioration of reflectance is smaller in reflection layers formed by sputtering using targets of Examples 103 to 120 than in full reflection layers formed by sputtering using targets of Conventional Examples 3 and 4 listed in Table 11 after keeping the layers within a thermo-hygrostat at a temperature of 80° C., at a relative humidity of 85%, for 200 hours. Whereas, as in Comparative Examples 18 to 21, Ag alloys containing totally more than 0.05 wt % of Ca, Be, and Si cannot be formed, for example, due to generation of cracking during the rolling,

[Experiment 8]

Dy, La, Nd, Td, and Gd each having purity of no less than 99.9 wt % were prepared. These raw materials were added to Ag, together with Cu and master Cu alloy containing Ni prepared in Experiment 6, and master Ag alloy containing Ca, Be or Si prepared in Experiment 7, and were melted within a radio frequency vacuum furnace. Ingots were produced by casting the molten metals in graphite molds under Ar gas atmosphere. The ingots were heated at 600° C. for 2 hours and subsequently subjected to rolling and mechanical working. Thus, Examples 121 to 145, and Comparative Examples 22 to 27, each having a diameter of 125 mm, thickness of 5 mm, and alloy composition listed in Tables 14 to 16 were produced.

Example 121 to 145, and Comparative Example 22 to 27 were respectively soldered to backing plates made of oxygen-free copper. Each backing plate was mounted on a direct-current magnetron sputtering equipment. By evacuation using a vacuum exhauster, atmospheric pressure inside the direct-current magnetron sputtering equipment was reduced to 1×10⁻⁴ Pa. After that, Ar gas was introduced into the sputtering equipment and a gas pressure of 1.0 Pa as a sputtering condition was obtained. Next, from a direct current power source, direct-current power of 100 W was applied to the target to generate a plasma between the target and a glass substrate which was placed opposite to the target in a parallel arrangement with an intervening spacing of 70 mm. By such an experiment, on glass substrates of 30 mm in diameter, and 0.5 mm in thickness, Ag alloy reflection films of 100 nm in thickness were formed.

Immediately after deposition of the Ag alloy reflection film, reflectance of each film was measured using a spectrophotometer. Subsequently, the Ag alloy reflection films were placed within a thermo-hygrostat and kept at a temperature of 80° C., at a relative humidity of 85%, for 200 hours. After that treatment, reflectance of each film was measured under the same condition. From the experimental results for reflectance, reflectance for wavelength of 400 nm, and 650 nm were respectively determined and are listed in Tables 14 to 16. From these data, durability of each film in data replaying were evaluated as a reflection film of an optical recording medium.

TABLE 14

| | | | | | | | | | | Reflectance | | Reflectance | |
|---|---|---|---|---|---|---|---|---|---|---|---|---|---|
| | | | | | | | | | | for | | for | |
| | | | | | | | | | | WL: 400 nm | | WL: 650 nm | |
| | | | | | | | | | | (%) | | (%) | |
| | | Component (wt %) | | | | | | | | As | After | As | After |
| Target | | Cu | Ni | Dy | La | Nd | Tb | Gd | Ag | formed | 200 hr | formed | 200 hr |
| Ex. | 121 | 2.01 | 0.96 | 0.11 | — | — | — | — | balance | 84 | 82 | 96 | 95 |
| | 122 | 2.02 | 1.01 | 1.02 | — | — | — | — | balance | 81 | 80 | 94 | 93 |
| | 123 | 2.02 | 1.02 | 2.10 | — | — | — | — | balance | 78 | 77 | 93 | 91 |
| | 124 | 2.00 | 1.00 | 2.99 | — | — | — | — | balance | 76 | 75 | 92 | 91 |
| | 125 | 2.01 | 1.01 | — | 0.10 | — | — | — | balance | 84 | 83 | 96 | 94 |
| | 126 | 2.02 | 1.02 | — | 1.01 | — | — | — | balance | 81 | 79 | 94 | 93 |
| | 127 | 2.02 | 1.00 | — | 2.00 | — | — | — | balance | 78 | 77 | 93 | 91 |
| | 128 | 2.00 | 0.99 | — | 2.98 | — | — | — | balance | 76 | 75 | 92 | 91 |
| | 129 | 2.01 | 1.03 | — | — | 0.11 | — | — | balance | 84 | 83 | 96 | 95 |
| | 130 | 2.02 | 1.01 | — | — | 1.10 | — | — | balance | 81 | 80 | 94 | 93 |
| | 131 | 2.00 | 1.01 | — | — | 2.09 | — | — | balance | 78 | 76 | 93 | 91 |
| | 132 | 2.02 | 1.02 | — | — | 2.90 | — | — | balance | 76 | 75 | 92 | 91 |
| | 133 | 2.00 | 1.01 | — | — | — | 0.12 | — | balance | 84 | 83 | 96 | 94 |
| | 134 | 2.01 | 1.00 | — | — | — | 1.11 | — | balance | 81 | 90 | 93 | 92 |

TABLE 15

| | | | | | | | | | | Reflectance | | Reflectance | |
|---|---|---|---|---|---|---|---|---|---|---|---|---|---|
| | | | | | | | | | | for | | for | |
| | | | | | | | | | | WL: 400 nm | | WL: 650 nm | |
| | | | | | | | | | | (%) | | (%) | |
| | | Component (wt %) | | | | | | | | As | After | As | After |
| Target | | Cu | Ni | Dy | La | Nd | Tb | Gd | Ag | formed | 200 hr | formed | 200 hr |
| Ex. | 135 | 2.01 | 1.03 | — | — | — | 2.10 | — | balance | 77 | 76 | 92 | 91 |
| | 136 | 2.02 | 1.01 | — | — | — | 2.97 | — | balance | 76 | 74 | 92 | 90 |
| | 137 | 2.00 | 1.05 | — | — | — | — | 0.11 | balance | 84 | 83 | 95 | 94 |
| | 138 | 2.01 | 1.02 | — | — | — | — | 0.99 | balance | 81 | 80 | 94 | 92 |
| | 139 | 2.02 | 1.03 | — | — | — | — | 2.01 | balance | 78 | 77 | 94 | 93 |
| | 140 | 2.02 | 1.01 | — | — | — | — | 2.89 | balance | 76 | 74 | 93 | 92 |
| | 141 | 2.00 | 0.06 | 0.05 | 0.05 | — | — | — | balance | 86 | 85 | 97 | 96 |
| | 142 | 2.01 | 0.12 | 1.02 | 1.20 | — | — | — | balance | 79 | 78 | 93 | 91 |
| | 143 | 2.02 | 0.54 | — | — | 0.11 | 1.13 | 1.52 | balance | 77 | 75 | 93 | 92 |
| | 144 | 2.00 | 1.03 | 0.91 | 0.57 | 1.01 | — | 1.00 | balance | 74 | 73 | 91 | 89 |
| | 145 | 2.00 | 1.51 | 0.58 | 0.57 | 0.61 | 0.62 | 0.61 | balance | 75 | 73 | 91 | 90 |

TABLE 16

| | | | | | | | | | | Reflectance | | Reflectance | | |
|---|---|---|---|---|---|---|---|---|---|---|---|---|---|---|
| | | | | | | | | | | for | | for | | |
| | | | | | | | | | | WL: 400 nm | | WL: 650 nm | | |
| | | | | | | | | | | (%) | | (%) | | |
| | | Component (wt %) | | | | | | | | As | After | As | After | |
| Target | | Cu | Al | Dy | La | Nd | Tb | Gd | Ag | formed | 200 hr | formed | 200 hr | Remark |
| COMP. | 22 | 2.01 | 1.00 | 3.3* | — | — | — | — | balance | — | — | — | — | Not |
| EX. | | | | | | | | | | | | | | formed |
| | 23 | 2.03 | 1.03 | — | 3.4* | — | — | — | balance | — | — | — | — | Not |
| | | | | | | | | | | | | | | formed |
| | 24 | 2.01 | 1.02 | — | — | 3.3* | — | — | balance | — | — | — | — | Not |
| | | | | | | | | | | | | | | formed |
| | 25 | 2.04 | 1.03 | — | — | — | 3.4* | — | balance | — | — | — | — | Not |
| | | | | | | | | | | | | | | formed |
| | 26 | 2.03 | 1.01 | — | — | — | — | 3.5* | balance | — | — | — | — | Not |
| | | | | | | | | | | | | | | formed |
| | 27 | 2.03 | 1.00 | 1.01 | 1.02 | 0.55 | 0.52 | 0.12 | balance | — | — | — | — | Not |
| | | | | | | | | | | | | | | formed |

From the results listed in Table 14 to 16, it is obvious that the degree of deterioration of reflectance is smaller in full reflection layers formed by sputtering using targets of Examples 121 to 145 than in full reflection layers formed by sputtering using targets of Conventional Examples 3 to 4 listed in Table 11 after keeping the layers within a thermo-hygrostat at a temperature of 80° C., at a relative humidity of 85%, for 200 hours. Whereas, as shown in Comparative Examples 22 to 27, Ag alloy containing Dy, La, Nd, Tb, and Gd totally more than 3 wt % could not be formed, for example, due to generation of cracking during the rolling.

[Experiment 9]

Using Cu and master Cu alloy containing Ni prepared in Experiment 6, master alloys containing Ca, Be, and Si prepared in Experiment 7, and Dy, La, Nd, Tb, and Gd prepared in Experiment 8, Examples 146 to 157 listed in Table 17 were formed. Using these targets, on glass substrates, Ag alloy reflection films of 100 nm in thickness were formed in a same manner as the Experiment 6. Reflectance of each film was measured using a spectrophotometer. After keeping the Ag alloy reflection films at a temperature of 80° C., at a relative humidity of 85%, for 200 hours, reflectance of each films was measured under the same condition. From the experimental results for reflectance, reflectances for wavelength of 400 nm, and 650 nm were respectively determined and are listed in Tables 17. From these data, durability in data replaying were evaluated as reflection films of an optical recording medium.

TABLE 17

| | | | | | | | | Reflectance | | Reflectance | |
|---|---|---|---|---|---|---|---|---|---|---|---|
| | | | | | | | | for | | for | |
| | | | | | | | | WL: 400 nm | | WL: 650 nm | |
| | | | | | | | | (%) | | (%) | |
| | | Component (wt %) | | | | | | As | After | As | After |
| Target | | Cu | Ni | Ca, Be, Si | Dy, La, Nd, Tb, Gd | | Ag | formed | 200 hr | formed | 200 hr |
| Ex. | 146 | 3.03 | 0.11 | Ca: 0.012 | Dy: 1.47 | | balance | 78 | 76 | 94 | 93 |
| | 147 | 2.02 | 0.52 | Be: 0.019 | La: 0.98 | | balance | 80 | 79 | 95 | 93 |
| | 148 | 3.05 | 1.03 | Si: 0.028 | Nd: 0.75 | | balance | 76 | 74 | 93 | 92 |
| | 149 | 1.03 | 1.52 | Ca: 0.015 | Tb: 0.51 | | balance | 81 | 80 | 95 | 94 |
| | | | | Si: 0.015 | | | | | | | |
| | 150 | 2.02 | 0.15 | Be: 0.030 | Gd: 0.22 | | balance | 82 | 80 | 95 | 94 |
| | 151 | 3.04 | 0.54 | Si: 0.031 | Dy: 0.04 | Gd: 0.08 | balance | 80 | 79 | 95 | 93 |
| | 152 | 1.01 | 0.99 | Ca: 0.015 | La: 0.06 | Tb: 0.15 | balance | 83 | 82 | 95 | 94 |
| | | | | Be: 0.017 | | | | | | | |
| | 153 | 2.10 | 1.48 | Be: 0.028 | Nd: 0.05 | Dy: 0.13 | balance | 80 | 78 | 94 | 93 |
| | 154 | 3.06 | 0.11 | Si: 0.030 | Tb: 1.01 | Nd: 1.02 | balance | 75 | 74 | 91 | 89 |
| | 155 | 1.01 | 0.50 | Ca: 0.025 | Gd: 1.45 | La: 1.43 | balance | 76 | 74 | 91 | 90 |
| | 156 | 2.12 | 1.01 | Be: 0.015 | Dy: 0.05 | Gd: 0.12 | balance | 82 | 81 | 94 | 92 |
| | | | | Si: 0.005 | Nd: 0.06 | | | | | | |
| | 157 | 3.10 | 1.49 | Si: 0.022 | La: 0.54 | Tb: 0.60 | balance | 72 | 70 | 89 | 88 |
| | | | | | Dy: 0.59 | Nd: 0.60 | | | | | |
| | | | | | Gd: 0.61 | | | | | | |

From the results listed in Table 17, it is obvious that the degree of deterioration of reflectance for wavelength of 400 nm and 650 nm is smaller in reflection layers formed by sputtering using targets of Examples 146 to 157 of the invention than in reflection layers formed by sputtering using targets of Conventional Examples 3 to 4 listed in Table 11 after keeping the layers within a thermo-hygrostat at a temperature of 80° C., at a relative humidity of 85%, for 200 hours.

### INDUSTRIAL APPLICABILITY

According to the present invention, compared with Ag or Ag alloy layers produced by sputtering using conventional Ag or Ag—Zn alloy sputtering targets, Ag alloy layers produced by sputtering using an Ag alloy target comprising an Ag—Zn alloy containing 0.1 to 20 wt % of Zn, and 0.1 to 3 wt % of Al have an effect that the layer show little coarsening of crystal grains by repeated heating and cooling due to repeated incidence of a laser beam, and show very little deterioration of reflectance after long-term use.

Compared with Ag alloy reflection layers produced by sputtering using a conventional Ag, Ag—Cu alloy, or Ag—Ni alloy targets, Ag alloy reflection layers produced by sputtering using a target of Ag alloy containing both Cu and Ni have similar effect as described above.

1. An Ag alloy sputtering target for producing full reflection layers and semi-reflection layers (both of which are hereafter called reflection layers) of optical recording mediums, the target comprising an Ag alloy containing 0.1 to 20 wt % of Zn, 0.1 to 3 wt % of Al, and a balance of Ag.

2. An Ag alloy sputtering target for producing reflection layers of optical recording mediums, the target comprising an Ag alloy containing 0.1 to 20 wt % of Zn, 0.1 to 3 wt % of Al, totally 0.005 to 0.05 wt % of one or more elements selected from Ca, Be, and Si, and a balance of Ag.

3. An Ag alloy sputtering target for producing reflection layers of optical recording mediums, the target comprising an Ag alloy containing 0.1 to 20 wt % of Zn, 0.1 to 3 wt % of Al, totally 0.1 to 3 wt % of one or more elements selected from Dy, La, Nd, Th, and Gd, and a balance of Ag.

4. An Ag alloy sputtering target for producing reflection layers of optical recording mediums, the target comprising an Ag alloy containing 0.1 to 20 wt % of Zn, 0.1 to 3 wt % of Al, totally 0.005 to 0.05 wt % of one or more elements selected from Ca, Be, and Si, totally 0.1 to 3 wt % of one or more elements selected from Dy, La, Nd, Tb, and Gd, and a balance of Ag.

5. A reflection layer of an optical recording medium comprising a deposition film produced using an Ag alloy sputtering target according to any one of claims 1, 2, 3 or 4.

6. An Ag alloy sputtering target for producing full reflection layers of optical recording mediums, the target comprising an Ag alloy containing 1 to 20 wt % of Zn, 0.5 to 3 wt % of Al, and a balance of Ag.

7. An Ag alloy sputtering target for producing full reflection layers of optical recording mediums, the target comprising an Ag alloy containing 1 to 20 wt % of Zn, 0.5 to 3 wt % of Al, totally 0.005 to 0.05 wt % of one or more elements selected from Ca, Be, and Si, and a balance of Ag.

8. An Ag alloy sputtering target for producing full reflection layers of optical recording mediums, the target comprising an Ag alloy containing 1 to 20 wt % of Z%, 0.5 to 3 wt % of Al, totally 0.1 to 3 wt % of one or more elements selected from Dy, La, Nd, Th, and Gd, and a balance of Ag.

9. An Ag alloy sputtering target for producing fill reflection layers of optical recording mediums, the target comprising an Ag alloy containing 1 to 20 wt % of Zn, 0.5 to 3 wt % of Al, totally 0.005 to 0.05 wt % of one or more elements selected from Ca, Be, and Si, and totally 0.1 to 3 wt % of one or more elements selected from Dy, La, Nd, Tb, and Gd, and a balance of Ag.

10. A full reflection layer of an optical recording medium comprising a deposition film produced using an Ag alloy sputtering target according to any one of claims 6, 7, 8 or 9.

11. An Ag alloy sputtering target for producing semi-reflection layers of optical recording mediums, the target comprising an Ag alloy containing 0.1 to less than 1 wt % of Zn, 0.1 to less than 0.5 wt % of Al, and a balance of Ag.

12. An Ag alloy sputtering target for producing semi-reflection layers of optical recording mediums, the target comprising an Ag alloy containing 0.1 to less than 1 wt % of Zn, 0.1 to less than 0.5 wt % of Al, totally 0.005 to 0.05 wt % of one or more elements selected from Ca, Be, and Si, and a balance of Ag.

13. A semi-reflection layer of an optical recording medium comprising deposition films produced using an Ag alloy sputtering target according to any one of claims 11 or 12.

14. An Ag alloy sputtering target for producing reflection layers of optical recording mediums, the target comprising an Ag alloy containing 0.5 to 5 wt % of Cu, 0.05 to 2 wt % of Ni. and a balance of Ag.

15. An Ag alloy sputtering target for producing reflection layers of optical recording mediums, the target comprising an Ag alloy containing 0.5 to 5 wt % of Cu, 0.05 to 2 wt % of Ni, additionally containing totally 0.005 to 0.05 wt % of one or more elements selected from Ca, Be, and Si, and a balance of Ag.

16. An Ag alloy sputtering target for producing reflection layers of optical recording mediums, the target comprising an Ag alloy containing 0.5 to 5 wt % of Cu, 0.05 to 2 wt % of Ni, additionally containing totally 0.1 to 3 wt % of one or more elements selected from Dy, La, Nd, Th, and Gd, and a balance of Ag.

17. An Ag alloy sputtering target for producing reflection layers of optical recording mediums, the target comprising an Ag alloy containing 0.5 to 5 wt % of Cu. 0.05 to 2 wt % of Ni, totally 0.005 to 0.0 5 wt % of one or more elements selected from Ca, Be, Si, totally 0.1 to 3 wt % of one or more elements selected from Dy, La, Nd, Th, and Gd, and a balance of Ag.

18. A reflection layer of an optical recording medium, comprising deposition film produced using an Ag alloy sputtering target according to any one of claims 14, 15, 16 or 17.
